(19) United States
(12) Patent Application Publication
(10) Pub. No.: US 2016/0099102 A1
(43) Pub. Date: Apr. 7, 2016

(54) ELECTRONIC COMPONENT

(71) Applicant: MURATA MANUFACTURING CO., LTD., Kyoto (JP)

(72) Inventor: Minoru MATSUNAGA, Nagaokakyo-shi (JP)

(73) Assignee: MURATA MANUFACTURING CO., LTD., Kyoto (JP)

(21) Appl. No.: 14/872,823

(22) Filed: Oct. 1, 2015

(30) Foreign Application Priority Data
Oct. 3, 2014 (JP) 2014-205136

(51) Int. Cl. H01F 27/40; H05F 3/02; H01F 27/28

(52) U.S. Cl. CPC H01F 27/402; H01F 27/2804; H05F 3/02; H01F 2027/2809

(57) ABSTRACT

An electronic component has a laminated body, a circuit element disposed in the laminated body, an electrostatic discharge element disposed in the laminated body, a circuit-element external electrode electrically connecting the electrostatic discharge element and the circuit element, and a grounding external electrode connected to the electrostatic discharge element for electrically connecting the electrostatic discharge element to the ground. The electrostatic discharge element is disposed closer to a first end surface of the laminated body as compared to the circuit element. A height of the grounding external electrode at an end portion closer to the circuit element from the first end surface is lower than a height of the circuit element at an end portion closer to the grounding external electrode from the first end surface.

### CROSS REFERENCE TO RELATED APPLICATIONS

This application claims benefit of priority to Japanese Patent Application No. 2014-205136 filed Oct. 3, 2014, the entire content of which is incorporated herein by reference.

### TECHNICAL FIELD

The present disclosure relates to an electronic component including a common mode choke coil and an electrostatic discharge element, for example.

### BACKGROUND

Conventional electronic components include an electronic component described in Japanese Patent Publication No. 2010-28695. The electronic component has a laminated body including a plurality of laminated insulation layers, a circuit element disposed in the laminated body, an electrostatic discharge element disposed in the laminated body, a circuit-element external electrode electrically connecting the electrostatic discharge element and the circuit element, and a grounding external electrode connected to the electrostatic discharge element for electrically connecting the electrostatic discharge element to the ground.

The laminated body has a first end surface and a second end surface arranged in a lamination direction of the insulation layers and located on the opposite sides of each other. The grounding external electrode extends continuously from the first end surface to the second end surface of the laminated body.

### SUMMARY

### Problem to be Solved by the Disclosure

Since the conventional electronic component has the grounding external electrode extending continuously from the first end surface to the second end surface of the laminated body, the grounding external electrode covers the circuit element in a direction orthogonal to the lamination direction of the laminated body. This may lead to an increase in stray capacitance generated between the grounding external electrode and the circuit element and deteriorate electric characteristics (high frequency characteristics).

It is therefore a problem of the present disclosure to provide an electronic component reducing the stray capacitance to improve the electric characteristics.

### Solutions to the Problems

To solve the problem, an electronic component of the present disclosure comprises

a laminated body including a plurality of laminated insulation layers;

a circuit element disposed in the laminated body;

an electrostatic discharge element disposed in the laminated body;

a circuit-element external electrode electrically connecting the electrostatic discharge element and the circuit element; and

a grounding external electrode connected to the electrostatic discharge element for electrically connecting the electrostatic discharge element to the ground,

the laminated body has a first end surface and a second end surface arranged in a lamination direction of the insulation layers and located on the opposite sides of each other,

the electrostatic discharge element is disposed closer to the first end surface of the laminated body as compared to the circuit element,

a height of the grounding external electrode at an end portion closer to the circuit element from the first end surface is lower than a height of the circuit element at an end portion closer to the grounding external electrode from the first end surface.

According to the electronic component of the present disclosure, the electrostatic discharge element is disposed closer to the first end surface of the laminated body as compared to the circuit element and the height of the grounding external electrode at the end portion closer to the circuit element from the first end surface is lower than a height of the circuit element at the end position closer to the grounding external electrodes from the first end surface. As a result, the grounding external electrode does not overlap with at least a portion of the circuit element on a plane orthogonal to the lamination direction, and the grounding external electrode is separated from the circuit element in the lamination direction. Therefore, when the first end surface of the laminated body is mounted on the mounting substrate to use the electronic component, the stray capacitance generated between the grounding external electrode and the circuit element is reduced and the electric characteristics (high frequency characteristics) are improved.

In the electronic component of an embodiment, preferably, the first end surface of the laminated body is a mounted surface mounted on a mounting substrate.

According to the electronic component of the embodiment, the first end surface of the laminated body is a mounted surface mounted on the mounting substrate. Therefore, since the electrostatic discharge element is disposed closer to the mounted surface as compared to the circuit element, static electricity is more easily discharged to the mounting substrate. Since the electrostatic discharge element is disposed closer to the mounted surface as compared to the circuit element, the gravity center of the electronic component is made closer to the mounted surface and the attitude of the electronic component becomes stable when the electronic component is mounted on the mounting substrate.

In the electronic component of an embodiment, preferably, the grounding external electrode is disposed continuously from the first end surface of the laminated body to a side surface between the first end surface and the second end surface of the laminated body.

According to the electronic component of the embodiment, the grounding external electrode is disposed continuously from the first end surface of the laminated body to the side surface. Therefore, if the grounding external electrode is mounted via solder on the mounting substrate, the solder is connected also to a portion of the grounding external electrode disposed on the side surface of the laminated body and the reliability is increased in the connection between the electronic component and the mounting substrate.

In the electronic component of an embodiment, preferably,

the side surface of the laminated body has a concave portion cut out from the first end surface and extended from the first end surface toward the second end surface, and

the grounding external electrode is fitted into the concave portion of the laminated body.

According to the electronic component of the embodiment, the grounding external electrode is fitted into the concave portion of the side surface of the laminated body. Therefore, when the thickness of the laminated body of the electronic component is set constant in aside surface direction, a thickness can be made smaller in a portion of the grounding external electrode exposed from the side surface of the laminated body and, thus, the thickness of the laminated body can be made larger in the side surface direction. By making the thickness of the laminated body larger in the side surface direction in this way, the circuit element can be designed in a larger size and the electric characteristics (e.g., inductance value) as the circuit element can be improved.

In the electronic component of an embodiment, preferably,

in the grounding external electrode, a contact portion contacting an inner surface of the concave portion of the laminated body has a step-like shape extending from the first end surface toward the second end surface,

in the inner surface of the concave portion of the laminated body, a contact portion contacting the grounding external electrode has a step-like shape extending from the first end surface toward the second end surface, and

the contact portion of the grounding external electrode and the contact portion of the laminated body engage with each other.

According to the electronic component of the embodiment, the contact portion of the grounding external electrode has a step-like shape while the contact portion of the laminated body has a step-like shape, and the contact portion of the grounding external electrode and the contact portion of the laminated body engage with each other. Therefore, the grounding external electrode hardly comes off from the laminated body.

In the electronic component of an embodiment, preferably,

the first end surface of the laminated body has a hole portion having an opening in the first end surface and extending from the first end surface toward the second end surface, and

the grounding external electrode is fitted into the hole portion of the laminated body.

According to the electronic component of the embodiment, the grounding external electrode is fitted into the hole portion of the first end surface of the laminated body. Therefore, when the thickness of the laminated body of the electronic component is set constant in a side surface direction, a thickness can be eliminated in the portion of the grounding external electrode exposed from the side surface of the laminated body and, thus, the thickness of the laminated body can be made larger in the side surface direction. By making the thickness of the laminated body larger in the side surface direction in this way, the circuit element can be designed in a larger size and the electric characteristics of the circuit element can be improved. Since the grounding external electrode is covered in the laminated body, the grounding external electrode can be prevented from being damaged due to contact with other electronic components and devices.

In the electronic component of an embodiment, preferably,

in the grounding external electrode, a contact portion contacting an inner surface of the hole portion of the laminated body has a step-like shape extending from the first end surface toward the second end surface,

in the inner surface of the hole portion of the laminated body, a contact portion contacting the grounding external electrode has a step-like shape extending from the first end surface toward the second end surface, and

the contact portion of the grounding external electrode and the contact portion of the laminated body engage with each other.

According to the electronic component of the embodiment, the contact portion of the grounding external electrode has a step-like shape while the contact portion of the laminated body has a step-like shape, and the contact portion of the grounding external electrode and the contact portion of the laminated body engage with each other. Therefore, the grounding external electrode hardly comes off from the laminated body.

In the electronic component of an embodiment, preferably, a distance between the electrostatic discharge element and the circuit element is 50 μm or more.

According to the electronic component of the embodiment, the distance between the electrostatic discharge element and the circuit element is 50 μm or more. As a result, the electrostatic discharge element is separated from the circuit element and the insulation layer between the electrostatic discharge element and the circuit element is made thick. Therefore, a common mode impedance is made higher and a noise reduction effect is improved.

In the electronic component of an embodiment, preferably, a distance between the electrostatic discharge element and the first end surface of the laminated body is 50 μm or more.

According to the electronic component of the embodiment, the distance between the electrostatic discharge element and the first end surface of the laminated body is 50 μm or more. As a result, although a gap must be formed between multiple discharge electrodes making up the electrostatic discharge element, the gap between the discharge electrodes can be separated from the first end surface of the laminated body. Therefore, even if an impact etc. are applied to the electronic component when the first end surface of the laminated body is mounted on the mounting substrate, the electronic component can be prevented from breaking, chipping, and cracking.

In the electronic component of an embodiment, preferably, the insulation layers contain metal magnetic powder.

According to the electronic component of the embodiment, the insulation layers contain the metal magnetic powder and therefore can improve the characteristics (such as an inductance value and direct-current superimposition characteristics) of the electronic component.

### Effect of the Disclosure

According to the electronic component of the present disclosure, since the electrostatic discharge element is disposed closer to the first end surface of the laminated body as compared to the circuit element and the height of the grounding external electrode at the end portion closer to the circuit element from the first end surface is lower than the height of the circuit element at the end portion closer to the grounding external electrode from the first end surface, therefore, the stray capacitance is reduced to improve the electric characteristics.

### BRIEF DESCRIPTION OF DRAWINGS

FIG. 1 is a perspective view of an electronic component of a first embodiment of the present disclosure.

FIG. 2 is a cross-sectional view of the electronic component.

FIG. 3 is an exploded perspective view of the electronic component.

FIG. 4 is a circuit diagram of the electronic component.

FIG. 5 is a simplified configuration diagram of the electronic component.

FIG. 6 is a simplified configuration diagram of an electronic component of a second embodiment of the present disclosure.

FIG. 7A is a graph of a relationship between a distance from an electrostatic discharge element to a circuit element and a common impedance.

FIG. 7B is a graph of a relationship between a distance from the electrostatic discharge element to a first end surface of a laminated body and the strength of the electronic component.

FIG. 8 is a simplified configuration diagram of an electronic component of a third embodiment of the present disclosure.

FIG. 9A is an explanatory view for explaining a method of manufacturing the electronic component.

FIG. 9B is an explanatory view for explaining the method of manufacturing the electronic component.

FIG. 9C is an explanatory view for explaining the method of manufacturing the electronic component.

FIG. 9D is an explanatory view for explaining the method of manufacturing the electronic component.

FIG. 9E is an explanatory view for explaining the method of manufacturing the electronic component.

FIG. 9F is an explanatory view for explaining the method of manufacturing the electronic component.

FIG. 10 is a simplified configuration diagram of an electronic component of a fourth embodiment of the present disclosure.

FIG. 11A is an explanatory view for explaining a method of manufacturing the electronic component.

FIG. 11B is an explanatory view for explaining the method of manufacturing the electronic component.

FIG. 11C is an explanatory view for explaining the method of manufacturing the electronic component.

FIG. 11D is an explanatory view for explaining the method of manufacturing the electronic component.

FIG. 11E is an explanatory view for explaining the method of manufacturing the electronic component.

FIG. 11F is an explanatory view for explaining the method of manufacturing the electronic component.

### DETAILED DESCRIPTION

The present disclosure will now be described in detail in terms of shown embodiments.

### First Embodiment

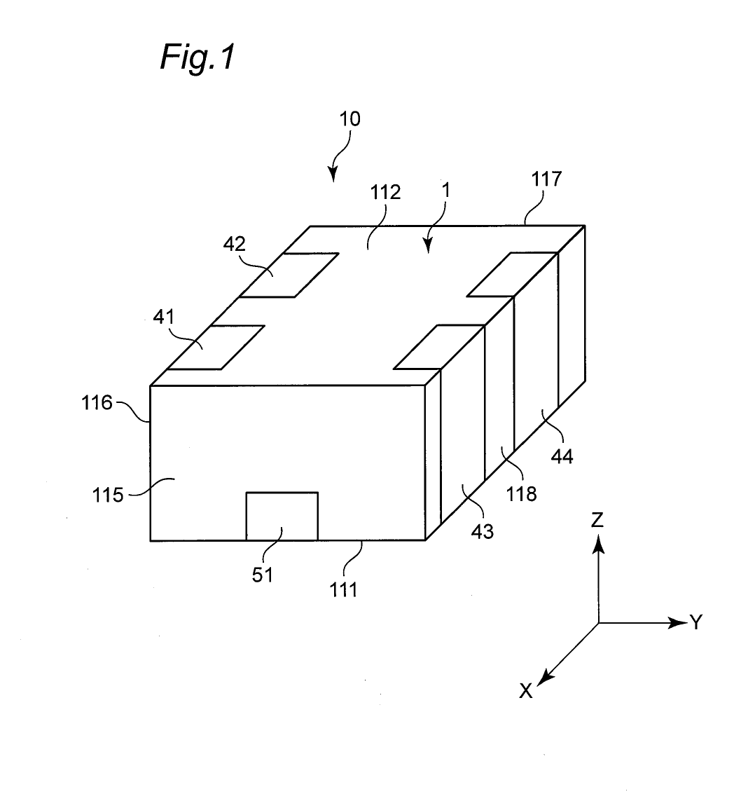

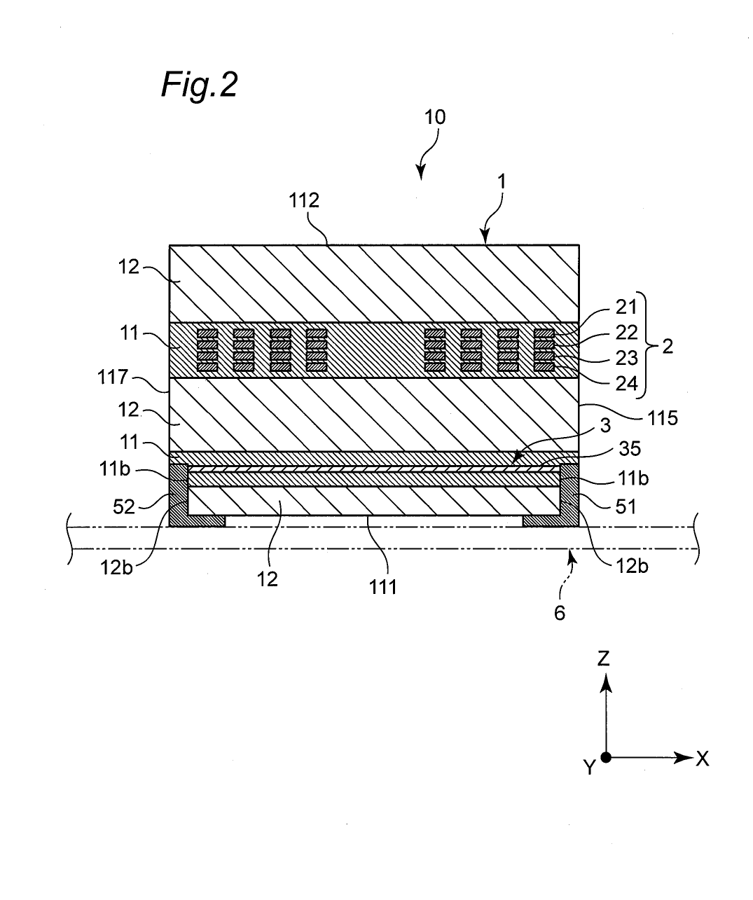

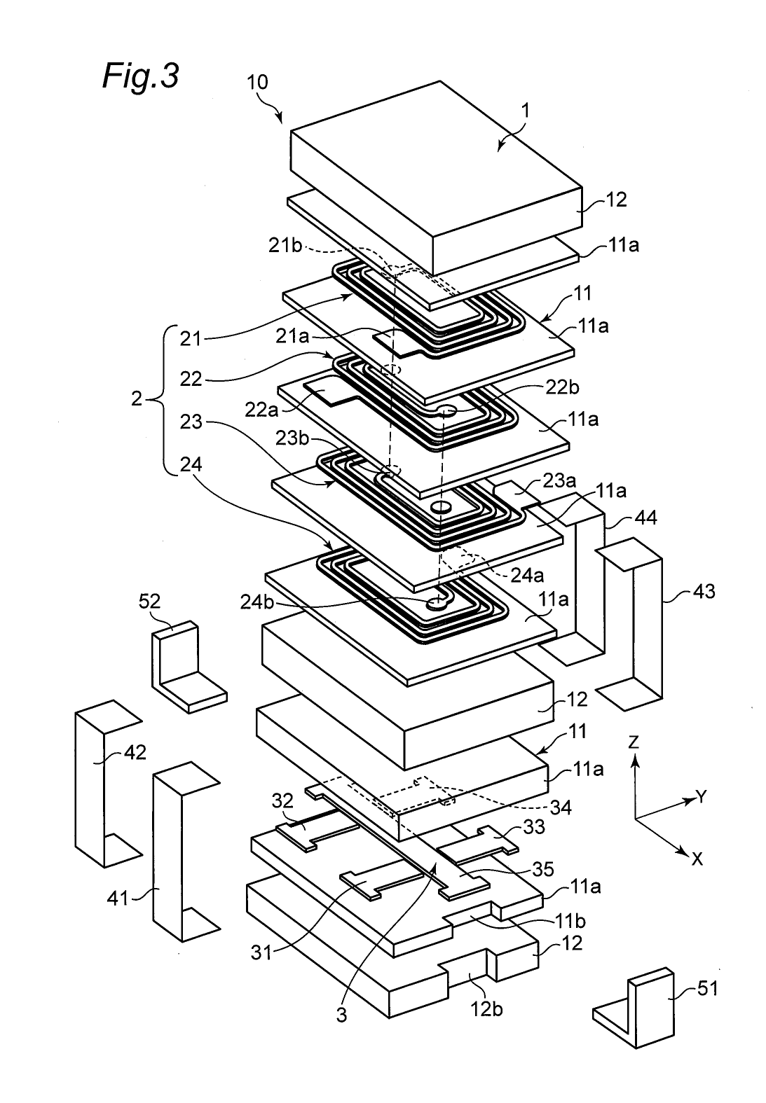

FIG. 1 is a perspective view of an electronic component of a first embodiment of the present disclosure. FIG. 2 is a cross-sectional view of the electronic component. FIG. 3 is an exploded perspective view of the electronic component. As shown in FIGS. 1, 2, and 3, an electronic component 10 has a laminated body 1, a circuit element 2 disposed in the laminated body 1, an electrostatic discharge element 3 disposed in the laminated body 1, first to fourth circuit-element external electrodes 41 to 44 electrically connecting the electrostatic discharge element 3 and the circuit element 2, and first and second grounding external electrodes 51, 52 connected to the electrostatic discharge element 3 for electrically connecting the electrostatic discharge element 3 to the ground.

The electronic component 10 is electrically connected to a mounting substrate 6. The electronic component 10 is mounted on an electronic device such as a personal computer, a DVD player, a digital camera, a TV, a portable telephone, and automotive electronics, for example.

The laminated body 1 includes a plurality of laminated insulation layers. The insulation layers include non-magnetic bodies 11 and magnetic bodies 12. The non-magnetic bodies 11 are made of, for example, a resin material, a glass material, and a glass-ceramic. The magnetic bodies 12 are made of a magnetic material such as ferrite. Preferably, the insulation layers contain metal magnetic powder and can thereby improve the characteristics (such as an inductance value and direct-current superimposition characteristics) of the electronic component 10.

The laminated body 1 is formed into a substantially rectangular parallelepiped shape. The lamination direction of the laminated body 1 is defined as a Z-axis direction and a direction along the long sides of the laminated body 1 is defined as an X-axis direction while a direction along the short sides of the laminated body 1 is defined as a Y-axis direction. X-, Y-, and Z-axes are orthogonal to each other. The upper side of the figures is defined as the upward side of the Z-axis direction and the lower side of the figures is defined as the downward side of the Z-axis direction.

The surface of the laminated body 1 has a first end surface 111, a second end surface 112, a first side surface 115, a second side surface 116, a third side surface 117, and a fourth side surface 118. The first end surface 111 and the second end surface 112 are arranged on the opposite sides of each other in the lamination direction (Z-axis direction). The first to fourth side surfaces 115 to 118 are located between the first end surface 111 and the second end surface 112.

The first end surface 111 is a mounted surface mounted on the mounting substrate 6 and is located on the lower side. The first side surface 115 and the third side surface 117 are short side surfaces and are arrange on the opposite sides of each other in the X-axis direction. The second side surface 116 and the fourth side surface 118 are long side surfaces and are arranged on the opposite sides of each other in the Y-axis direction.

The circuit element 2 is a common mode choke coil. The circuit element 2 has first to fourth coils 21 to 24 from the top to the bottom. Each of the first to fourth coils 21 to 24 is disposed on a non-magnetic sheet 11a. The first to fourth coils 21 to 24 are made of an electrically conductive material such as Ag, Ag—Pd, Cu, and Ni, for example. The first to fourth coils 21 to 24 are formed by, for example, printing and baking the electrically conductive material on the non-magnetic sheet 11a.

The first to fourth coils 21 to 24 are helically wound in the same direction when viewed from above. The first coil 21 has an extraction electrode 21a at one end of a helical shape thereof on the outer circumferential side, and the first coil 21 has a pad 21b at the other end at the center of the helical shape. Similarly, the second coil 22 has an extraction electrode 22a and a pad 22b; the third coil 23 has an extraction electrode 23a and a pad 23b; and the fourth coil 24 has an extraction electrode 24a and a pad 24b.

The extraction electrode 21a of the first coil 21 is exposed from the second side surface 116 on the side closer to the first side surface 115; the extraction electrode 22a of the second coil 22 is exposed from the second side surface 116 on the side closer to the third side surface 117; the extraction electrode 23a of the third coil 23 is exposed from the fourth side surface 118 on the side closer to the first side surface 115; and the extraction electrode 24a of the fourth coil 24 is exposed from the fourth side surface 118 on the side closer to the third side surface 117.

The pad 21b of the first coil 21 and the pad 23b of the third coil 23 are electrically connected via a via hole conductor disposed in the non-magnetic sheet 11a. The pad 22b of the second coil 22 and the pad 24b of the fourth coil 24 are electrically connected via a via hole conductor disposed in the non-magnetic sheet 11a.

The electrostatic discharge element (ESD element) 3 includes first to fifth discharge electrodes 31 to 35. The first to fifth discharge electrodes 31 to 35 are sandwiched by upper and lower non-magnetic sheets 11a. The first to fourth discharge electrodes 31 to 34 extend in the Y-axis direction. The fifth discharge electrode 35 extends in the X-axis direction.

One end portion of the first discharge electrode 31 is exposed from the second side surface 116 on the side closer to the first side surface 115 and the other end portion of the first discharge electrode 31 is located at the center of the non-magnetic body 11 in the Y-direction. One end portion of the second discharge electrode 32 is exposed from the second side surface 116 on the side closer to the third side surface 117 and the other end portion of the second discharge electrode 32 is located at the center of the non-magnetic body 11 in the Y-direction.

One end portion of the third discharge electrode 33 is exposed from the fourth side surface 118 on the side closer to the first side surface 115 and the other end portion of the third discharge electrode 33 is located at the center of the non-magnetic body 11 in the Y-direction. One end portion of the fourth discharge electrode 34 is exposed from the fourth side surface 118 on the side closer to the third side surface 117 and the other end portion of the fourth discharge electrode 34 is located at the center of the non-magnetic body 11 in the Y-direction.

One end portion of the fifth discharge electrode 35 is located in a gap between the other end portion of the first discharge electrode 31 and the other end portion of the third discharge electrode 33. A gap for electric discharge is formed between the one end portion of the fifth discharge electrode 35 and the other end portion of the first discharge electrode 31. A gap for electric discharge is disposed between the one end portion of the fifth discharge electrode 35 and the other end portion of the third discharge electrode 33.

The other end of the fifth discharge electrode 35 is located in a gap between the other end portion of the second discharge electrode 32 and the other end portion of the fourth discharge electrode 34. A gap for electric discharge is formed between the other end portion of the fifth discharge electrode 35 and the other end portion of the second discharge electrode 32. A gap for electric discharge is disposed between the other end portion of the fifth discharge electrode 35 and the other end portion of the fourth discharge electrode 34.

The gaps for electric discharge may not have any member present therein or may be filled with a material facilitating an electric discharge. Examples of the material facilitating an electric discharge include coated particles and semiconductor particles. The coated particles are metal particles such as Cu having surfaces coated with inorganic material such as alumina. The semiconductor particles are particles of semiconductor material such as SiC. The coated particles and the semiconductor particles are preferably dispersedly disposed. Dispersing the coated particles and the semiconductor particles facilitates the prevention of a short circuit and the adjustment of ESD characteristics such as a discharge starting voltage.

One end portion of the fifth discharge electrode 35 is exposed from the first side surface 115 and the other end portion of the fifth discharge electrode 35 is exposed from the third side surface 117.

The electrostatic discharge element 3 is disposed closer to the first end surface 111 of the laminated body 1 (on the lower side) as compared to the circuit element 2. The circuit-side non-magnetic body 11 covering the circuit element 2 and the discharge-side non-magnetic body 11 covering the electrostatic discharge element 3 are sandwiched by the upper and lower magnetic bodies 12, 12. The magnetic body 12 is disposed between the circuit-side non-magnetic body 11 and the discharge-side non-magnetic body 11.

The first to fourth circuit-element external electrodes 41 to 44 are made of an electrically conductive material such as Ag, Ag—Pd, Cu, and Ni, for example. The first to fourth circuit-element external electrodes 41 to 44 are formed by, for example, applying and baking the electrically conductive material on the surface of the laminated body 1. Each of the first to fourth circuit-element external electrodes 41 to 44 is formed into a U-shape.

The first circuit-element external electrode 41 is disposed on the second side surface 116 on the side closer to the first side surface 115. One end portion of the first circuit-element external electrode 41 is bent from the second side surface 116 and disposed on the first end surface 111. The other end portion of the first circuit-element external electrode 41 is bent from the second side surface 116 and disposed on the second end surface 112. The first circuit-element external electrode 41 electrically connects the extraction electrode 21a of the first coil 21 of the circuit element 2 and the one end portion of the first discharge electrode 31 of the electrostatic discharge element 3.

The second circuit-element external electrode 42 is disposed on the second side surface 116 on the side closer to the third side surface 117. The shape of the second circuit-element external electrode 42 is the same as the shape of the first circuit-element external electrode 41 and therefore will not be described. The second circuit-element external electrode 42 electrically connects the extraction electrode 22a of the second coil 22 of the circuit element 2 and the one end portion of the second discharge electrode 32 of the electrostatic discharge element 3.

The third circuit-element external electrode 43 is disposed on the fourth side surface 118 on the side closer to the first side surface 115. The shape of the second circuit-element external electrode 43 is the same as the shape of the first circuit-element external electrode 41 and therefore will not be described. The third circuit-element external electrode 43 electrically connects the extraction electrode 23a of the third coil 23 of the circuit element 2 and the one end portion of the third discharge electrode 33 of the electrostatic discharge element 3.

The fourth circuit-element external electrode 44 is disposed on the fourth side surface 118 on the side closer to the third side surface 117. The shape of the fourth circuit-element external electrode 44 is the same as the shape of the first circuit-element external electrode 41 and therefore will not be described. The fourth circuit-element external electrode 44 electrically connects the extraction electrode 24a of the fourth coil 24 of the circuit element 2 and the one end portion of the fourth discharge electrode 34 of the electrostatic discharge element 3.

The first and second grounding external electrodes 51, 52 are made of an electrically conductive material such as Ag, Ag—Pd, Cu, and Ni, for example. The first and second grounding external electrodes 51, 52 are formed by, for example, applying and baking the electrically conductive material on a concave portion of the surface of the laminated body 1. Each of the first and second grounding external electrodes 51, 52 is formed into an L-shape.

The first grounding external electrode 51 is disposed continuously from the first end surface 111 to the first side surface 115. The first grounding external electrode 51 electrically connects the one end portion of the fifth discharge electrode 35 and a grounding wiring not shown of the mounting substrate 6.

The first grounding external electrode 51 extends downward from the fifth discharge electrode 35. The non-magnetic body 11 and the magnetic body 12 located under the fifth discharge electrode 35 have respective concave portions 11b, 12b on the side of the first side surface 115. The concave portion 11b of the non-magnetic body 11 and the concave portion 12b of the magnetic body 12 are integrally continued. The concave portions 11b, 12b are cut out from the first end surface 111 and extended from the first end surface 111 toward the second end surface 112. The first grounding external electrode 51 is fitted into the concave portions 11b, 12b. Therefore, a portion of the first grounding external electrode 51 is exposed from the first side surface 115 of the laminated body 1.

The second grounding external electrode 52 is disposed continuously from the first end surface 111 to the third side surface 117. The second grounding external electrode 52 electrically connects the other end portion of the fifth discharge electrode 35 and the grounding wiring not shown of the mounting substrate 6.

The second grounding external electrode 52 extends downward from the fifth discharge electrode 35. The non-magnetic body 11 and the magnetic body 12 located under of the fifth discharge electrode 35 have respective concave portions 11b, 12b on the side of the third side surface 117. The concave portions 11b, 12b are cut out from the first end surface 111 and extended from the first end surface 111 toward the second end surface 112. The second grounding external electrode 52 is fitted into the concave portions 11b, 12b. Therefore, a portion of the second grounding external electrode 52 is exposed from the third side surface 117 of the laminated body 1.

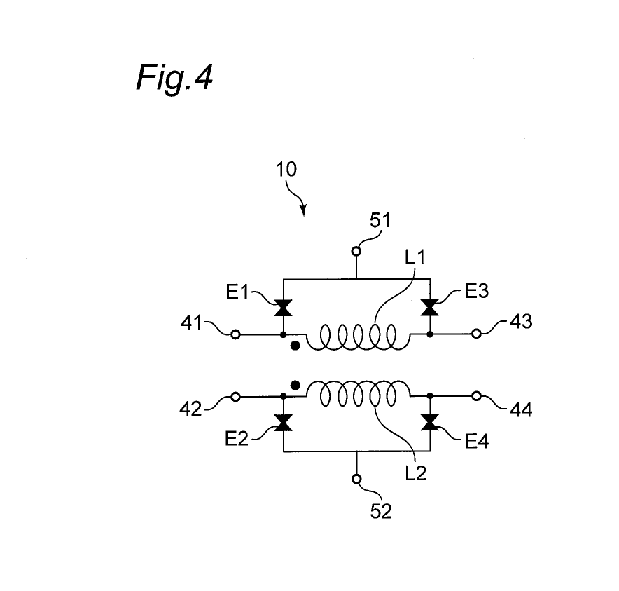

FIG. 4 is a circuit diagram of the electronic component 10. As shown in FIG. 4, a first coil group L1 made up of the first coil 21 and the third coil 23 is connected between the first circuit-element external electrode 41 and the third circuit-element external electrode 43. A first discharge group E1 made up of the first discharge electrode 31 and the fifth discharge electrode 35 is connected to a path from between the first coil group L1 and the first circuit-element external electrode 41 to the first grounding external electrode 51. A third discharge group E3 made up of the third discharge electrode 33 and the fifth discharge electrode 35 is connected to a path from between the first coil group L1 and the third circuit-element external electrode 43 to the first grounding external electrode 51.

A second coil group L2 made up of the second coil 22 and the fourth coil 24 is connected between the second circuit-element external electrode 42 and the fourth circuit-element external electrode 44. A second discharge group E2 made up of the second discharge electrode 32 and the fifth discharge electrode 35 is connected in a path from between the second coil group L2 and the second circuit-element external electrode 42 to the second grounding external electrode 52. A fourth discharge group E4 made up of the fourth discharge electrode 34 and the fifth discharge electrode 35 is connected in a path from between the second coil group L2 and the fourth circuit-element external electrode 44 to the second grounding external electrode 52.

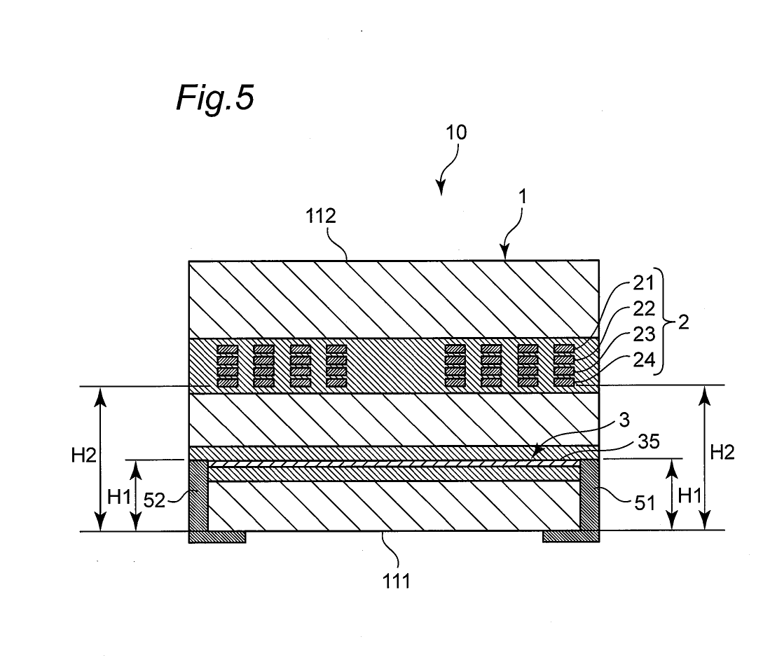

FIG. 5 is a simplified configuration diagram of the electronic component 10. As shown in FIG. 5, a height H1 of the first grounding external electrode 51 at the end position closer to the circuit element 2 from the first end surface 111 is lower than a height H2 of the circuit element 2 at the end portion closer to the first grounding external electrode 51 from the first end surface 111. Specifically, the height H1 of the upper end surface of the first grounding external electrode 51 from the first end surface 111 is lower than the height H2 of the lower end surface of the fourth coil 24 of the circuit element 2 from the first end surface 111. The upper end surface of the second grounding external electrode 52 is at the same height as the upper end surface of the first grounding external electrode 51.

A method of manufacturing the electronic component 10 will be described.

As shown in FIG. 3, the materials of the first to fourth coils 21 to 24 are applied by, for example, printing, to the respective different non-magnetic sheets 11a. The materials of the first to fifth discharge electrodes 31 to 35 are applied by, for example, printing, to the different non-magnetic sheet 11a.

The non-magnetic sheets 11a having the materials of the first to fourth coils 21 to 24 applied thereon, the non-magnetic sheet 11a having the materials of the first to fifth discharge electrodes 31 to 35 applied thereon, and a plurality of the magnetic bodies 12 are laminated and subjected to thermocompression bonding to dispose the circuit element 2 and the electrostatic discharge element 3 in the laminated body 1.

Subsequently, the materials of the first to fourth circuit-element external electrodes 41 to 44 are applied by, for example, printing, to the surface of the laminated body 1, and the materials of the first and second grounding external electrodes 51, 52 are applied by, for example, printing, to the surface of the laminated body 1, and these materials are baked to form the first to fourth circuit-element external electrodes 41 to 44 and the first and second grounding external electrodes 51, 52 on the surface of the laminated body 1. In this way, the electronic component 10 is manufactured.

According to the electronic component 10, the electrostatic discharge element 3 is disposed closer to the first end surface 111 of the laminated body 1 as compared to the circuit element 2 and the height H1 of the grounding external electrodes 51, 52 at the end portions closer to the circuit element 2 from the first end surface 111 is lower than the height H2 of the circuit element 2 at the end positions closer to the grounding external electrodes 51, 52 from the first end surface 111. As a result, the grounding external electrodes 51, 52 do not overlap with at least a portion of the circuit element 2 on a plane (XY plane) orthogonal to the lamination direction (Z-direction), and the grounding external electrodes 51, 52 are separated from the circuit element 2 in the lamination direction (Z-direction). Therefore, when the first end surface 111 of the laminated body 1 is mounted on the mounting substrate 6 to use the electronic component 10, the stray capacitance generated between the grounding external electrodes 51, 52 and the circuit element 2 is reduced and the electric characteristics (high frequency characteristics) are improved. The second end surface 112 of the laminated body 1 may be mounted on the mounting substrate 6 to use the electronic component 10.

In contrast, if the height H1 of the grounding external electrodes 51, 52 from the first end surface 111 is the same as or higher than the height H2 of the circuit element 2 from the first end surface 111, the stray capacitance generated between the grounding external electrodes 51, 52 and the circuit element 2 increases, deteriorating the electric characteristics.

The first end surface 111 of the laminated body 1 is a mounted surface mounted on the mounting substrate 6. Therefore, since the electrostatic discharge element 3 is disposed closer to the mounted surface as compared to the circuit element 2, static electricity is more easily discharged to the mounting substrate 6. Since the electrostatic discharge element 3 is disposed closer to the mounted surface as compared to the circuit element 2, the gravity center of the electronic component 10 is made closer to the mounted surface and the attitude of the electronic component 10 becomes stable when the electronic component 10 is mounted on the mounting substrate 6. Therefore, the electronic component 10 can be prevented from overturning.

The grounding external electrodes 51, 52 are disposed continuously from the first end surface 111 of the laminated body 1 to the side surfaces 115, 117. Therefore, if the grounding external electrodes 51, 52 are mounted via solder on the mounting substrate 6, the solder is connected also to the portions of the grounding external electrodes 51, 52 disposed on the side surfaces 115, 117 of the laminated body 1 and the reliability is increased in the connection between the electronic component 10 and the mounting substrate 6.

The grounding external electrodes 51, 52 are fitted into the concave portions 11b, 12b of the side surfaces 115, 117 of the laminated body 1. Therefore, when the thickness of the laminated body 1 of the electronic component 10 is set constant in a side surface direction, a thickness can be made smaller in the portions of the grounding external electrodes 51, 52 exposed from the side surfaces 115, 117 of the laminated body 1 and, thus, the thickness of the laminated body 1 can be made larger in the side surface direction. By making the thickness of the laminated body 1 larger in the side surface direction in this way, the circuit element 2 can be designed in a larger size and the electric characteristics (e.g., inductance value) of the circuit element 2 can be improved.

### Second Embodiment

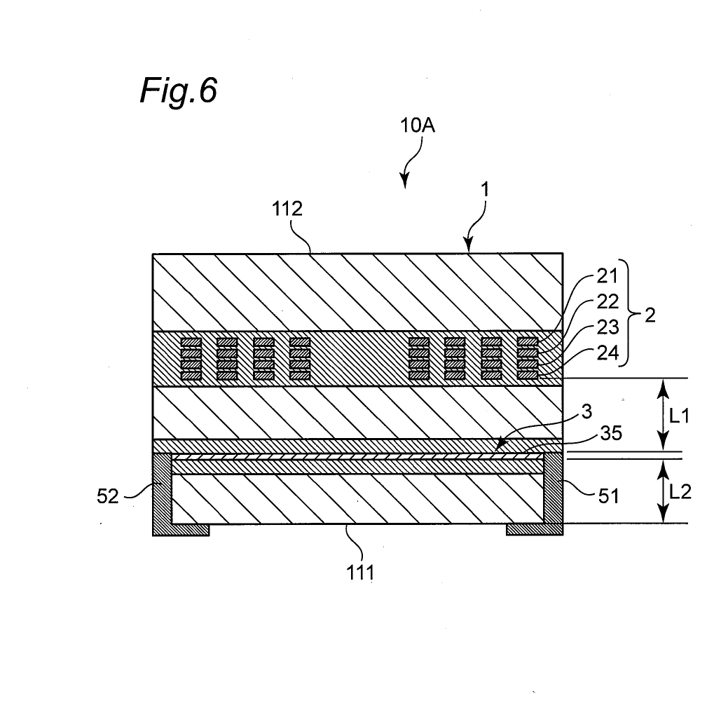

FIG. 6 is a simplified configuration diagram of an electronic component of a second embodiment of the present disclosure. The second embodiment is different from the first embodiment in distance between the electrostatic discharge element and the circuit element and in distance between the electrostatic discharge element and the first end surface of the laminated body. Only the different configuration will hereinafter be described. In the second embodiment, the same constituent elements as the first embodiment are denoted by the same reference numerals as the first embodiment and therefore will not be described.

As shown in FIG. 6, a distance L1 between the electrostatic discharge element 3 and the circuit element 2 is 50 μm or more. Specifically, the distance L1 between an end portion of the electrostatic discharge element 3 closer to the circuit element 2 (an upper end surface of the fifth discharge electrode 35) and an end portion of the circuit element 2 closer to the electrostatic discharge element 3 (a lower end surface of the fourth coil 24) is 50 μm or more.

Therefore, since the distance L1 between the electrostatic discharge element 3 and the circuit element 2 is 50 μm or more, the electrostatic discharge element 3 is separated from the circuit element 2 and the insulation layer (the magnetic body 12) between the electrostatic discharge element 3 and the circuit element 2 is made thick. As a result, a common mode impedance is made higher and a noise reduction effect is improved.

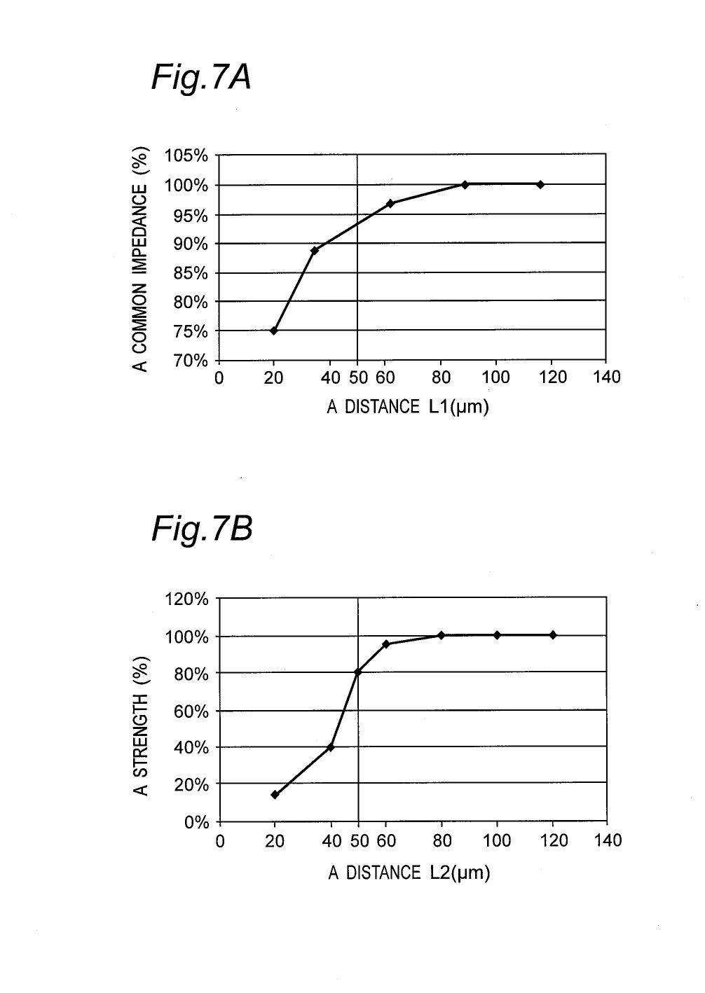

FIG. 7A shows a relationship between the distance L1 and a common impedance. The horizontal axis indicates the distance L1 (μm) and the vertical axis indicates the common impedance (%) at 100 MHz. As shown in FIG. 7A, when the distance L1 is 50 μm or more, the common mode impedance is high. On the other hand, if the distance L1 is smaller than 50 μm, the common mode impedance is low.

As shown in FIG. 6, a distance L2 between the electrostatic discharge element 3 and the first end surface 111 of the laminated body 1 is 50 μm or more. Specifically, the distance L2 between an end portion of the electrostatic discharge element 3 closer to the first end surface 111 (a lower end surface of the fifth discharge electrode 35) and the first end surface 111 is 50 μm or more.

For electrostatic discharge by the electrostatic discharge element 3, gaps must be formed between the first to fifth discharge electrodes 31 to 35 making up the electrostatic discharge element 3. Since the distance L2 between the electrostatic discharge element 3 and the first end surface 111 is 50 μm or more, the gaps between the discharge electrodes 31 to 35 can be separated from the first end surface 111 of the laminated body 1. Therefore, even if an impact etc. are applied to the electronic component 10 when the first end surface 111 of the laminated body 1 is mounted on the mounting substrate 6, the electronic component 10 can be prevented from breaking, chipping, and cracking.

FIG. 7B shows a relationship between the distance L2 and the strength of the electronic component 10. The horizontal axis indicates the distance L2 (μm) and the vertical axis indicates the strength (%) of the electronic component 10. As shown in FIG. 7B, when the distance L2 is 50 μm or more, the strength of the electronic component 10 is large. On the other hand, when the distance L2 is smaller than 50 μm, the strength of the electronic component 10 is small.

### Third Embodiment

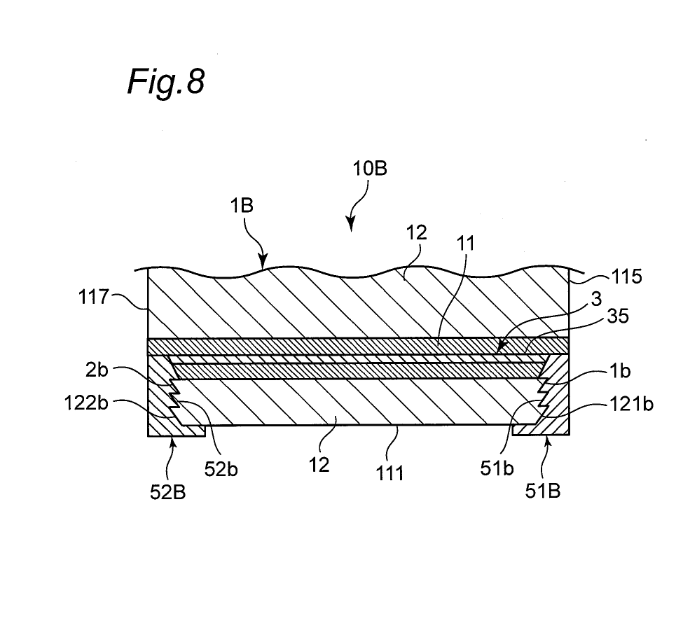

FIG. 8 is a simplified configuration diagram of an electronic component of a third embodiment of the present disclosure. The third embodiment is different from the first embodiment in the shape of the grounding external electrode. Only the different configuration will hereinafter be described. In the third embodiment, the same constituent elements as the first embodiment are denoted by the same reference numerals as the first embodiment and therefore will not be described.

As shown in FIG. 8, in an electronic component 10B of the third embodiment, the side surfaces 115, 117 of a laminated body 1B have concave portions 121b, 122b cut out from the first end surface 111 and extended from the first end surface 111 toward the second end surface 112. A first grounding external electrode 51B is fitted into the concave portion 121b of the laminated body 1B. A second grounding external electrode 52B is fitted into the concave portion 122b of the laminated body 1B.

In the first grounding external electrode 51B, a contact portion 51b contacting an inner surface of the concave portion 121b of the laminated body 1B has a step-like shape extending from the first end surface 111 toward the second end surface 112. In the inner surface of the concave portion 121b of the laminated body 1B, a contact portion 1b contacting the first grounding external electrode 51B has a step-like shape extending from the first end surface 111 toward the second end surface 112. The contact portion 51b of the first grounding external electrode 51B and the contact portion 1b of the inner surface of the laminated body 1B engage with each other.

Similarly, in the second grounding external electrode 52B, a contact portion 52b contacting an inner surface of the concave portion 122b of the laminated body 1B has a step-like shape. In the inner surface of the concave portion 122b of the laminated body 1B, a contact portion 2b contacting the second grounding external electrode 52B has a step-like shape. The contact portion 52b of the second grounding external electrode 52B and the contact portion 2b of the inner surface of the laminated body 1B engage with each other.

Therefore, since the step-like contact portions 51b, 52b of the first and second grounding external electrodes 51B, 52B and the step-like contact portions 1b, 2b of the inner surfaces of the laminated body 1B engage with each other, the first and second grounding external electrodes 51B, 52B hardly come off from the inner surfaces of the laminated body 1B.

A method of manufacturing the first and second grounding external electrode 51B, 52B will be described.

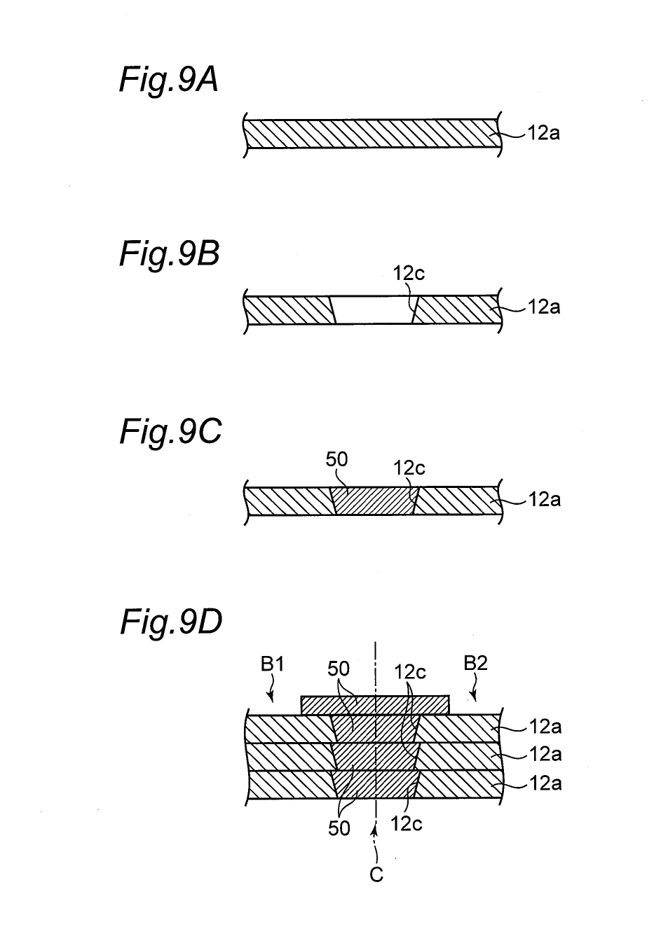

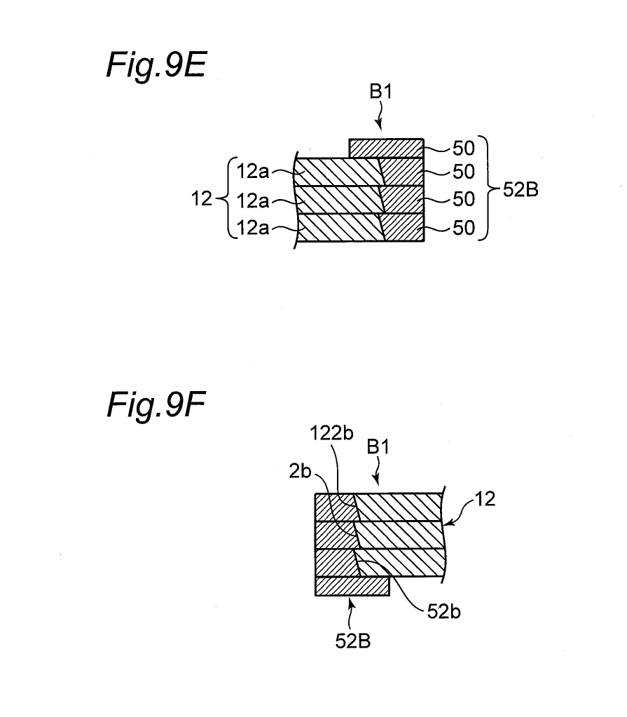

As shown in FIG. 9A, a magnetic body sheet 12a is prepared, and as shown in FIG. 9B, a hole 12c is formed in the magnetic body sheet 12a by a construction method using a laser etc. The inner surface of the hole 12c is formed into a tapered shape. As shown in FIG. 9C, the hole 12c is filled and printed with an electrically conductive material 50 such as Ag.

Subsequently, as shown in FIG. 9D, a plurality of the magnetic body sheets 12a printed with the electrically conductive materials 50 is laminated and an upper surface of the top magnetic body sheet 12a is printed with the electrically conductive material 50. In this case, the centers of the holes 12c of a plurality of the magnetic body sheets 12a are matched. As a result, the electrically conductive materials 50 of a plurality of the magnetic body sheets 12a are laminated and connected.

Subsequently, the magnetic body sheets 12a are cut at the center C of the holes 12c into two members B1, B2 and, as shown in FIG. 9E, the one member B1 is selected. As shown in FIG. 9F, the one member B1 is inverted to manufacture the second grounding external electrode 52B embedded in the magnetic body 12. Since the inner surfaces of the holes 12c of the magnetic body sheets 12a are formed into the tapered shape, the contact portion 52b of the second grounding external electrode 52B is formed into a step-like shape, and the contact portion 2b of the inner surface of the concave portion 122b of the laminated body 1B is formed into a step-like shape. The other member B2 is manufactured in the same way as the one member B1. The first grounding external electrode 51B is manufactured in the same way as the second grounding external electrode 52B.

### Fourth Embodiment

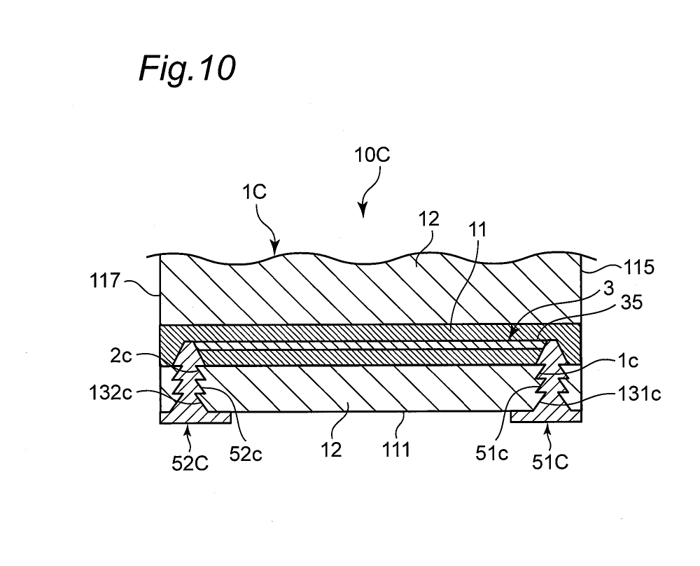

FIG. 10 is a simplified configuration diagram of an electronic component of a fourth embodiment of the present disclosure. The fourth embodiment is different from the first embodiment in the shape of the grounding external electrode. Only the different configuration will hereinafter be described. In the fourth embodiment, the same constituent elements as the first embodiment are denoted by the same reference numerals as the first embodiment and therefore will not be described.

As shown in FIG. 10, in an electronic component 10C of the fourth embodiment, a first end surface 111 of a laminated body 1C has hole portions 131c, 132c having an opening in the first end surface 111 and extending from the first end surface 111 toward the second end surface 112. A first grounding external electrode 51C is fitted into the hole portion 131c of the laminated body 1C. A second grounding external electrode 52C is fitted into the hole portion 132c of the laminated body 1C. Therefore, the first and second grounding external electrode 51C, 52C are not exposed from the side surfaces 115, 117 of the laminated body 1C.

Therefore, when the thickness of the laminated body 1C of the electronic component 10 is set constant in a side surface direction, a thickness can be eliminated in the portions of the first and second grounding external electrodes 51C, 52C exposed from the side surfaces 115, 117 of the laminated body 1C and, thus, the thickness of the laminated body 1C can be made larger in the side surface direction. By making the thickness of the laminated body 1C larger in the side surface direction in this way, the circuit element 2 can be designed in a larger size and the electric characteristics of the circuit element 2 can be improved. Since the first and second grounding external electrodes 51C, 52C are covered in the laminated body 1C, the first and second grounding external electrodes 51C, 52C can be prevented from being damaged due to contact with other electronic components and devices.

In the first grounding external electrode 51C, a contact portion 51c contacting an inner surface of the hole portion 131c of the laminated body 1C has a step-like shape extending from the first end surface 111 toward the second end surface 112. In the inner surface of the hole portion 131c of the laminated body 1C, the contact portion 1c contacting the first grounding external electrode 51C has a step-like shape extending from the first end surface 111 toward the second end surface 112. The contact portion 51c of the first grounding external electrode 51C and the contact portion 1c of the inner surface of the laminated body 1C engage with each other.

Similarly, in the second grounding external electrode 52C, a contact portion 52c contacting an inner surface of the hole portion 132c of the laminated body 1C has a step-like shape. In the inner surface of the hole portion 132c of the laminated body 1C, the contact portion 2c contacting the second grounding external electrode 52C has a step-like shape. The contact portion 52c of the second grounding external electrode 52C and the contact portion 2c of the laminated body 1C engage with each other.

Therefore, since the step-like contact portions 51c, 52c of the first and second grounding external electrodes 51C, 52C and the step-like contact portions 1c, 2c of the inner surfaces of the laminated body 1C engage with each other, the first and second grounding external electrode 51C, 52C hardly come off from the laminated body 1C.

A method of manufacturing the first and second grounding external electrode 51C, 52C will be described.

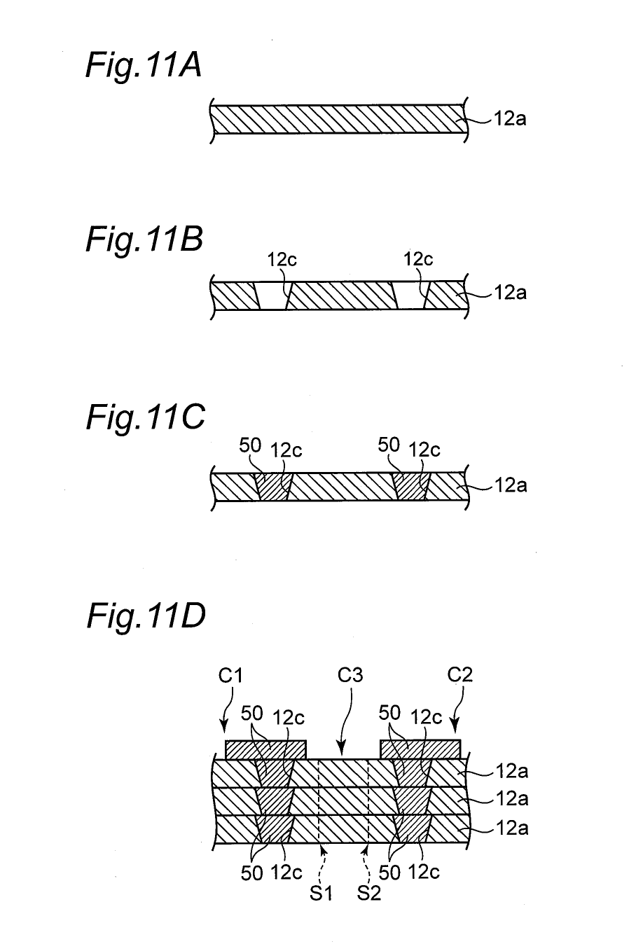

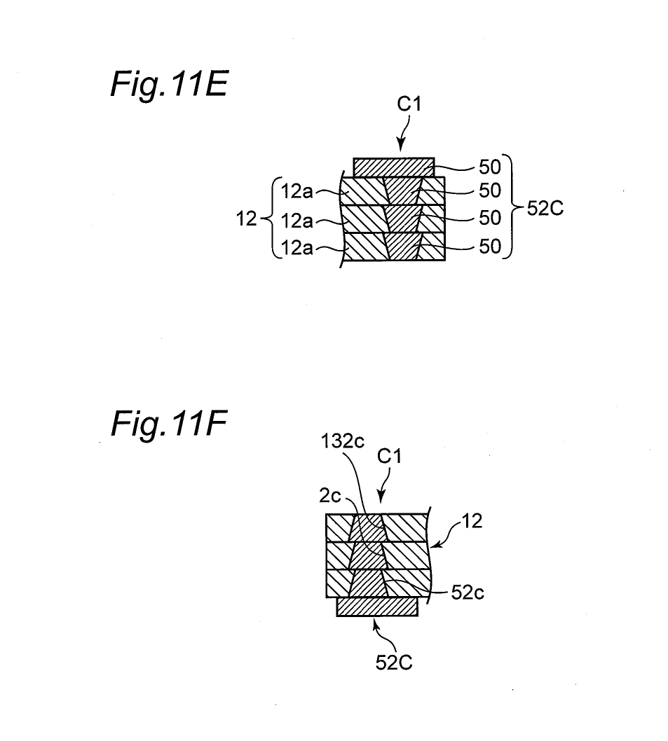

As shown in FIG. 11A, the magnetic body sheet 12a is prepared, and as shown in FIG. 11B, two adjacent holes 12c are formed in the magnetic body sheet 12a by a construction method using a laser etc. The inner surfaces of the holes 12c are formed into a tapered shape. As shown in FIG. 11C, the holes 12c are filled and printed with an electrically conductive material 50 such as Ag.

Subsequently, as shown in FIG. 11D, a plurality of the magnetic body sheets 12a printed with the electrically conductive materials 50 is laminated and an upper surface of the top magnetic body sheet 12a is printed with the electrically conductive material 50. In this case, the centers of the holes 12c of a plurality of the magnetic body sheets 12a are matched. As a result, the electrically conductive materials 50 of a plurality of the magnetic body sheets 12a are laminated and connected.

Subsequently, the magnetic body sheets 12a are cut at two cutting portions S1, S2 located between the two adjacent holes 12c into three members C1, C2, C3. Each of the first member C1 and the second member C2 is a member including the electrically conductive material 50. The third member C3 is a cut margin located between the first member C1 and the second member C2 without including the electrically conductive material 50.

Subsequently, as shown in FIG. 11E, the first member C1 is selected. As shown in FIG. 11F, the first member C1 is inverted to manufacture the second grounding external electrode 52C embedded in the magnetic body 12. Since the inner surfaces of the holes 12c of the magnetic body sheets 12a are formed into the tapered shape, the contact portion 52c of the second grounding external electrode 52C is formed into a step-like shape, and the contact portion 2c of the inner surface of the hole portion 132c of the laminated body 1C is formed into a step-like shape. The second member C2 is manufactured in the same way as the first member C1. The first grounding external electrode 51C is manufactured in the same way as the second grounding external electrode 52C.

The present disclosure is not limited to the embodiments and can be changed in design without departing from the spirit of the present disclosure. For example, respective feature points of the first to fourth embodiments may variously be combined.

Although four coils are used as the circuit element in the embodiments, two coils may be used. Although the circuit element is a common mode choke coil in the embodiments, other coils may be used.

The embodiments may satisfy either that the distance between the electrostatic discharge element and the circuit element is 50 μm or more or that the distance between the electrostatic discharge element and the first end surface of the laminated body is 50 μm or more.

Although the electrostatic discharge element is disposed closer to the mounting substrate as compared to the circuit element in the embodiments, the electronic component may be vertically inverted to dispose the circuit element closer to the mounting substrate as compared to the electrostatic discharge element. In this case, the electrostatic discharge element is not used.

1. An electronic component comprising:
a laminated body including a plurality of laminated insulation layers;
a circuit element disposed in the laminated body;
an electrostatic discharge element disposed in the laminated body;
a circuit-element external electrode electrically connecting the electrostatic discharge element and the circuit element; and
a grounding external electrode connected to the electrostatic discharge element for electrically connecting the electrostatic discharge element to the ground, wherein
the laminated body has a first end surface and a second end surface arranged in a lamination direction of the insulation layers and located on opposite sides from each other,
the electrostatic discharge element is disposed closer to the first end surface of the laminated body as compared to the circuit element, and
a height of the grounding external electrode at an end portion closer to the circuit element from the first end surface is lower than a height of the circuit element at an end portion closer to the grounding external electrode from the first end surface.

2. The electronic component of claim 1, wherein
the first end surface of the laminated body is a mounted surface mounted on a mounting substrate.

3. The electronic component of claim 1, wherein
the grounding external electrode is disposed continuously from the first end surface of the laminated body to a side surface between the first end surface and the second end surface of the laminated body.

4. The electronic component of claim 3, wherein
the side surface of the laminated body has a concave portion cut out from the first end surface and extended from the first end surface toward the second end surface, and
the grounding external electrode is fitted into the concave portion of the laminated body.

5. The electronic component of claim 4, wherein
in the grounding external electrode, a contact portion contacting an inner surface of the concave portion of the laminated body has a step-like shape extending from the first end surface toward the second end surface,
in the inner surface of the concave portion of the laminated body, a contact portion contacting the grounding external electrode has a step-like shape extending from the first end surface toward the second end surface, and
the contact portion of the grounding external electrode and the contact portion of the laminated body engage with each other.

6. The electronic component of claim 1, wherein
the first end surface of the laminated body has a hole portion having an opening in the first end surface and extending from the first end surface toward the second end surface, and
the grounding external electrode is fitted into the hole portion of the laminated body.

7. The electronic component of claim 6, wherein
in the grounding external electrode, a contact portion contacting an inner surface of the hole portion of the laminated body has a step-like shape extending from the first end surface toward the second end surface,
in the inner surface of the hole portion of the laminated body, a contact portion contacting the grounding external electrode has a step-like shape extending from the first end surface toward the second end surface, and
the contact portion of the grounding external electrode and the contact portion of the laminated body engage with each other.

8. The electronic component of claim 1, wherein
a distance between the electrostatic discharge element and the circuit element is 50 μm or more.

9. The electronic component of claim 1, wherein
a distance between the electrostatic discharge element and the first end surface of the laminated body is 50 μm or more.

10. The electronic component of claim 1, wherein
the insulation layers contain metal magnetic powder.
